(19) United States
(12) Patent Application Publication
(10) Pub. No.: US 2009/0249161 A1
(43) Pub. Date: Oct. 1, 2009

(54) METHOD OF RESTORING DATA

(75) Inventor: Hiroyuki Chiba, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/349,033

(22) Filed: Jan. 6, 2009

(30) Foreign Application Priority Data
Mar. 26, 2008 (JP) 2008-080254

(51) Int. Cl. H03M 13/05; G06F 11/07

(52) U.S. Cl. 714/752; 714/E11.021

(57) ABSTRACT

A method of restoring data from a stream of data segments each including first synchronization information followed by first user data information, second synchronization information, and second user data information, the method includes extracting first and second user data information on the basis of the first synchronization information, and converting the first and second user data information into reproduced data, and carrying out error recovery operation when the detecting of first synchronization information is not successful by a process having extracting second user data information on the basis of the detected second synchronization information, suspending the restoring of data in pipeline operation from another of the data segments subsequent to the certain data segment, and converting the second user data information into reproduced data while the restoring of data in pipeline operation is suspended.

### CROSS-REFERENCE TO RELATED APPLICATION

This application is based upon and claims the benefit of priority of the prior Japanese Patent Application No. 2008-80254, filed on Mar. 26, 2008, the entire contents of which are incorporated herein by reference.

### FIELD

A certain aspect of the embodiments discussed herein is related to a method of restoring data.

### BACKGROUND

As the information society advances, an amount of information handled is increasing more and more. A development of a storage device having a high memory capacity and permitting high-speed accessing is needed to meet the increase in the amount of information. In particular, a magnetic disk accessed by using a magnetic field draws attention as a high-density recording medium permitting information to be rewritten. A magnetic disk device includes such a magnetic disk and a head, and permits the head to access the magnetic disk for information. Research and development efforts have been actively made to develop an even higher capacity and higher speed magnetic disk device.

A zone bit recording (ZBR) method is widely used as one method of increasing an access speed. In the ZBR method, a magnetic disk is radially partitioned into a plurality of zones from the outer track thereof and information is written with an angular velocity kept constant within each zone. The ZBR method is characterized in that a track density BPI (bit per inch) is different from an outer track circle to an inner track circle. Since the rotation speed of the disk remains constant, a seek time can be shortened. In the magnetic disk device, pipeline control is adopted in a read channel, and the access speed is increased by performing in parallel demodulating of a signal read from the magnetic disk into non-return to zero (NRZ) data and transfer of the NRZ data.

In addition to user data as a target of information access, control data for use in head positioning and error correction is also recorded on the magnetic disk. To increase recording capacity and process speed on the magnetic disk, the recording area of the magnetic disk is partitioned into a plurality of sectors along a circular direction of each track. On a sector by sector basis, phase lock (PLO) data for adjusting frequency and amplitude, a sync mark indicating the start of the user data, the user data, error correction coding (ECC) data for error correction, etc. are successively recorded. There is a double-sync mark method. The user data is segmented into two by two sync marks, i.e., first user data is written in succession to a first sync mark and second user data is written in succession to a second sync mark. In accordance with the double-sync mark method, the first user data has a data length that permits the first user data to be restorable by the ECC data. If the detection of the first sync mark fails, the second sync mark is to be detected. The second user data is read and the first user data is restored using the ECC data. In this way, the reliability in the data reading is improved using the double-sync mark method.

The double-sync mark method is disclosed in a Japanese Laid-open Patent Publication No. 10-247303.

### SUMMARY

According to an aspect of an embodiment, a method of restoring data from a stream of data segments each including first synchronization information followed by first user data information, second synchronization information, and second user data information, the method has the steps of, restoring data from one of the data segments by a process including detecting first synchronization information in the one of the data segments, extracting first and second user data information on the basis of the first synchronization information, and converting the first and second user data information into reproduced data after a delay time from the detecting of the first synchronization information, repeating the restoring of data from another of the data segments such that data is successively restored in pipeline operation, and carrying out error recovery operation in the event that the detecting of first synchronization information in a certain data segment is not successful by a process having detecting second synchronization information in the certain data segment, extracting second user data information on the basis of the second synchronization information, suspending the restoring of data in pipeline operation from another of the data segments subsequent to the certain data segment, and converting the second user data information into reproduced data while the restoring of data in pipeline operation is suspended.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A, 1B and 1C are timing diagrams illustrating timings of pipeline control in a read channel;

FIG. 2 is a block diagram illustrating a hard disk device in accordance with one embodiment of the present art;

FIG. 3 is a signal flow chart of a read operation in accordance with one embodiment of the present art;

FIGS. 4A and 4B are flowcharts illustrating the read operation in accordance with one embodiment of the present art; and

FIGS. 5A, 5B and 5C are timing diagrams illustrating process timings of a read channel in accordance with one embodiment of the present art.

### DESCRIPTION OF EMBODIMENTS

If data is recorded on the magnetic disk using the above-described ZBR, the number of sectors between servo frames is different from the outer track circle to the inner track circle on the magnetic disk. For example, six sectors are included between servo frames along an outer track while five sectors are included between servo frames along an inner track. In the tracks between the outer track and the inner track, four or five sectors may be included between servo frames. One sector may be split into a plurality of segments depending on zone. The double-sync method and the ZBR method may be combined and a pipeline process may be performed using the read channel of the magnetic disk. In such a case, one sector is not split at a convenient place according to the related art, and one sector needs to be split so that a data length of each segment is larger than a minimum data length. The minimum data length L_min needs to satisfy the following equation:

Minimum data length L_min>delay time T+user data length L

where the delay time T lasts from when a signal is read to when the read signal is transferred, and the user data length L is time between the first sync mark and the second sync mark.

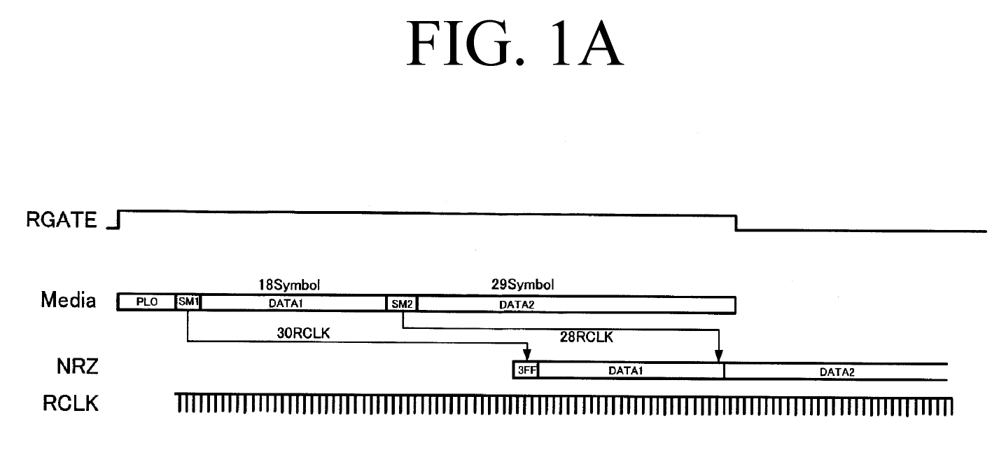

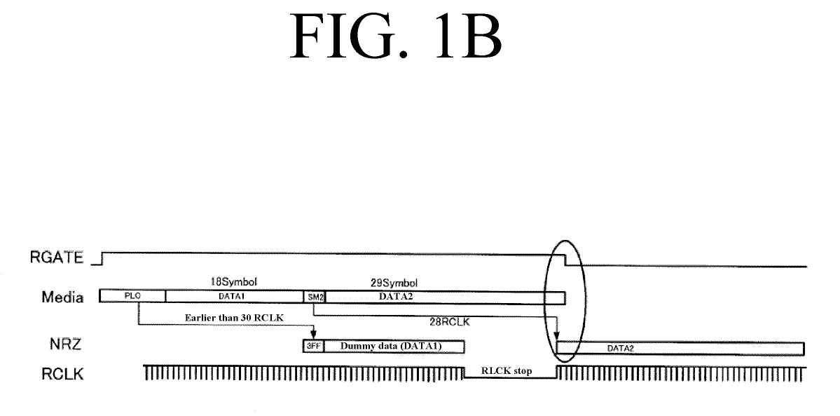

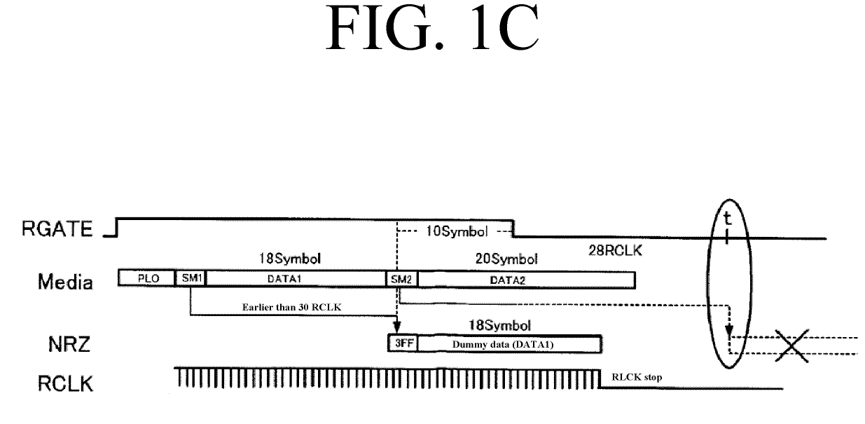

FIGS. 1A-1C is timing diagrams illustrating a timing of pipeline control of a read channel.

In the discussion that follows, the delay time T is 28 symbols long, the user data length L is 18 symbols long, and the minimum data length L_min is 46 symbols long.

FIG. 1A is a timing diagram in which the data length (47 symbols) of each segment which one sector is split into is larger than the minimum data length L_min (46 symbols) and the first sync mark has been successfully detected.

When a head of a sector to be read is detected, a hard disk controller in the magnetic disk device asserts a read gate and then negates the read gate after an elapse of read time corresponding to the data length. The read gate indicates a duration of time within which data is read from the magnetic disk. Only while the read gate is in an asserted state, data can be read from the magnetic disk.

When data recorded on the magnetic disk is read by the head of the magnetic disk device, the read signal is transferred to a read channel to detect a first sync mark in the read signal. If the first sync mark has successfully been detected, the first user data and the second user data are successively output to an NRZ unit in the read channel. After a delay time of about 30 clocks, the NRZ unit detects the first sync mark, and the first user data in succession to the first sync mark is demodulated into NRZ data. After another delay of about 28 clocks, the second user data is demodulated into NRZ data. If the first sync mark is detected, the read channel does not use the second sync mark. The NRZ unit thus successively demodulates the first user data and the second user data into the NRZ data.

FIG. 1B is a timing diagram in which the data length (47 symbols) of each segment which the sector is split into is larger than the minimum data length L_min (46 symbols) and the detection of the first sync mark has failed.

If the detection of the first sync mark in the read signal has failed, the hard disk controller outputs dummy data replacing the first user data to the NRZ unit at a timing earlier than normal, thereby negating a read clock and waiting on standby for the detection of the second sync mark. When the second sync mark is detected, the second sync mark and the second user data are successively output to the NRZ unit after a delay of about 28 clocks. When the second sync mark is detected, the NRZ unit asserts the read clock, and demodulates the second user data in succession to the second sync mark. The first user data is then restored using the ECC data. Referring to FIG. 1B, the read gate is on at the moment the second sync mark is transferred to the NRZ unit. The NRZ unit can thus detect the second sync mark, thereby performing an error recovery process.

FIG. 1C is a timing diagram in which the data length (38 symbols) of each segment which the sector is split into is smaller than the minimum data length L_min (46 symbols) and the detection of the first sync mark has failed.

If the detection of the first sync mark has failed as illustrated in FIG. 1C, the dummy data replacing the first user data is transferred to the NRZ unit. When the second sync mark is detected, the second sync mark and the second user data are successively transferred to the NRZ unit after a delay of about 28 clocks. However, since the read gate is negated at the moment the second sync mark is transferred to the NRZ unit, the NRZ unit cannot detect the second sync mark and cannot read the second user data.

If the double-sync method and the ZBR method are combined and the pipeline process is performed using the read channel of the magnetic disk, one sector needs to be split so that the data length of each segment is larger than the minimum data length.

When one sector is split by zone in accordance with the known method illustrated in FIGS. 1A-1C, a split method of splitting one sector into a first segment of 406 symbols and a second segment of 48 symbols is possible, but a split method of splitting one sector into a first segment of 414 symbols and a second segment of 40 symbols is not acceptable. Data of 48 symbols is now recorded. If a recording area of 40 symbols remains in the first segment, the data needs to be recorded on the second segment with the remaining recording area unused in the first segment. With this arrangement, track efficiency is low and recording capacity is reduced.

The embodiments of the present art are described below with reference to the drawings.

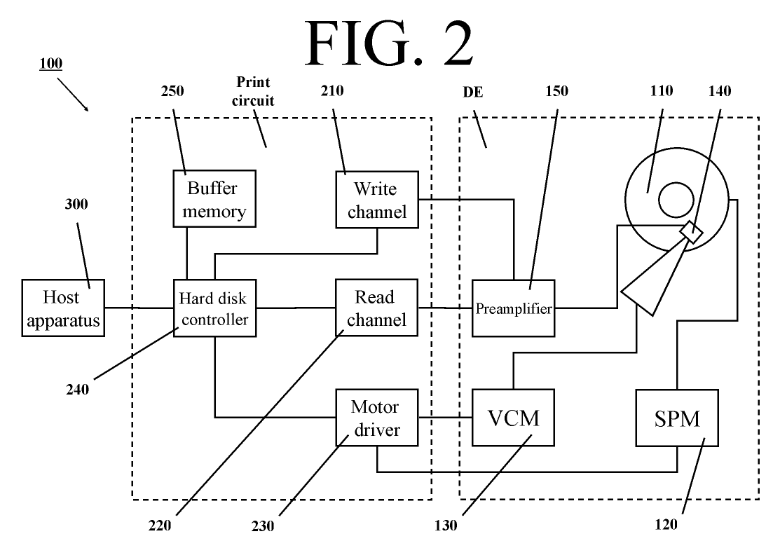

FIG. 2 diagrammatically illustrates a hard disk device 100.

The hard disk device 100 permits accessing to a magnetic disk 110 on which information is recorded in accordance with the double sync mark method and the ZBR method. In a typical configuration, the hard disk device 100 is connected to or built in a host apparatus 300, such as a personal computer.

Referring to FIG. 2, the hard disk device 100 includes the magnetic disk 110 on which information is recorded, a spindle motor 120 for spinning the magnetic disk 110, a magnetic head 140 accessing the magnetic disk 110 for information, a voice coil motor 130 for moving the magnetic head over and across the surface of the magnetic disk 110, a preamplifier 150 for amplifying a reproduced signal read by the magnetic head 140, a write channel 210 for generating a write current representing write data to be written on the magnetic disk 110, and a read channel 220 for demodulating the reproduced signal into digital NRZ data. The hard disk device 100 further includes a motor driver 230 for driving the spindle motor 120 and the voice coil motor 130, a hard disk controller 240 for exchanging data with the host apparatus 300, and a buffer memory 350 used by the hard disk controller 240. The magnetic disk 110 is one example of the previously described recording medium and the magnetic head 140 is one example of the previously described head. The read channel 220 is one example of the previously described data demodulating circuit.

When information is written on the magnetic disk 110, write information to be written onto the magnetic disk 110 and an address of the write position are transferred from the host apparatus 300 to hard disk device 100. The motor driver 230 drives the spindle motor 120, thereby spinning the magnetic disk 110. The motor driver 230 also drives the voice coil motor 130, thereby positioning the magnetic head 140 above the magnetic disk 110.

A write current bearing the write information is then applied to the magnetic head 140. The magnetic head 140 creates a magnetic field having a direction responsive to the write signal, thereby directing a magnetic flux responsive to the magnetic field to the magnetic disk 110. As a result, a magnetization occurs in a direction responsive to the write information, causing the information to be recorded on the magnetic disk 110.

When information recorded on the magnetic disk 110 is read, the address of the recording position of the recorded information is transferred from the host apparatus 300 to the hard disk device 100. In the same manner as in the information write operation, the spindle motor 120 operates, spinning the magnetic disk 110. The voice coil motor 130 operates, positioning the magnetic head 140 above the magnetic disk 110.

A reproducing element causing a resistance responsive to a magnetic field caused by magnetization is contained in the magnetic head 140. With a current flowing through the reproducing element, a reproduced signal is generated in response to a magnetization state. The reproduced signal is then demodulated into the NRZ data and the demodulated data is transferred to the host apparatus 300.

Accessing for information on the magnetic disk 110 is basically performed as described above.

A read process for reading information recorded on the magnetic disk 110 is described further in detail.

As described above, information is recorded on the magnetic disk 110 in accordance with the ZBR method and the double sync mark method. The magnetic disk 110 is partitioned into a plurality of sectors along a circular direction of each track. The magnetic disk 110 is further partitioned into a plurality of zones radially from the outer circle inward. Depending on the track, the border of zones splits the sector. Stored on each of a first segment and a second segment of the split sector are phase lock (PLO) data for adjusting frequency and amplitude, a first sync mark indicating the start of first user data, the first user data, a second sync mark indicating the start of second user data, the second user data, error correction coding (ECC) data, etc. The data length of the first user data is defined as a data length that allows the first user data to be restorable with the ECC data (18 symbols in this embodiment). A stream of data segments includes first synchronization information followed by first user data information, second synchronization information, and second user data information. The stream of data segments is restored. The first and second user data information is converted into reproduced data after a delay time from the detecting of the first synchronization information.

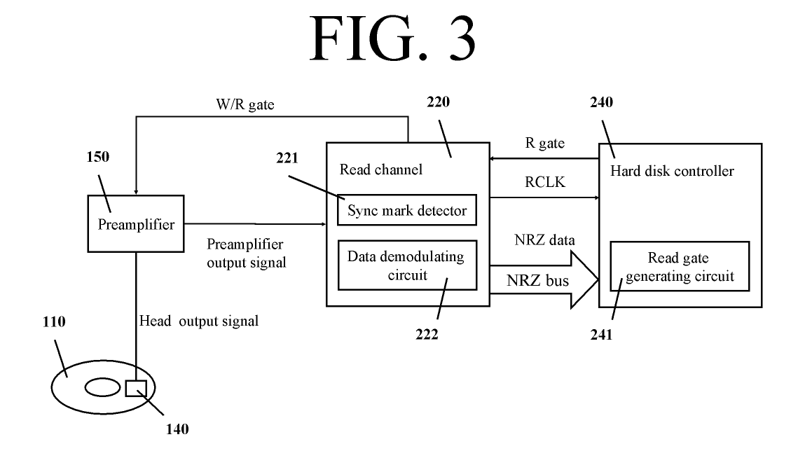

FIG. 3 illustrates a signal flow in a read process.

Referring to FIG. 3, the read channel 220 includes a sync mark detector 221 for detecting the first sync mark and the second sync mark, and a data demodulating circuit 222 for demodulating an analog reproduced signal into NRZ data. The hard disk controller 240 includes a read gate generating circuit 241 for controlling the read gate. The sync mark detector 221 is one example of the previously described sync mark unit. The data demodulating circuit 222 is one example of the previously described demodulating unit. The read gate generating circuit 241 is one example of the previously described read gate controller.

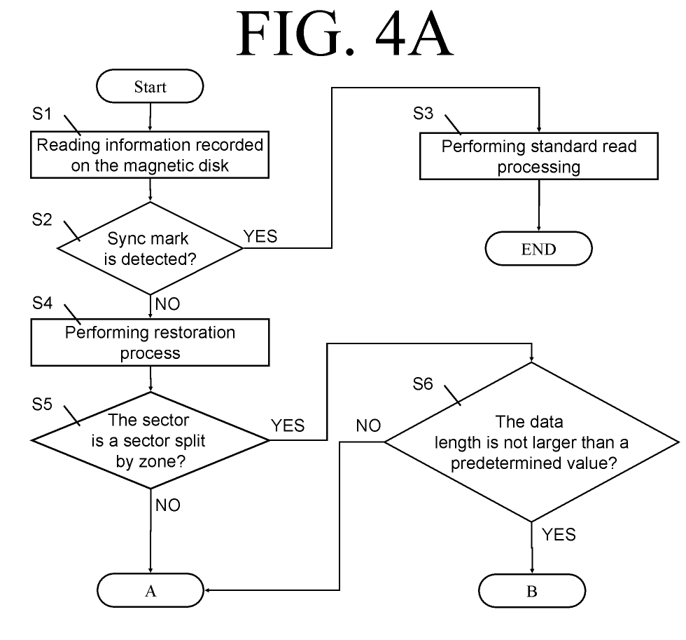

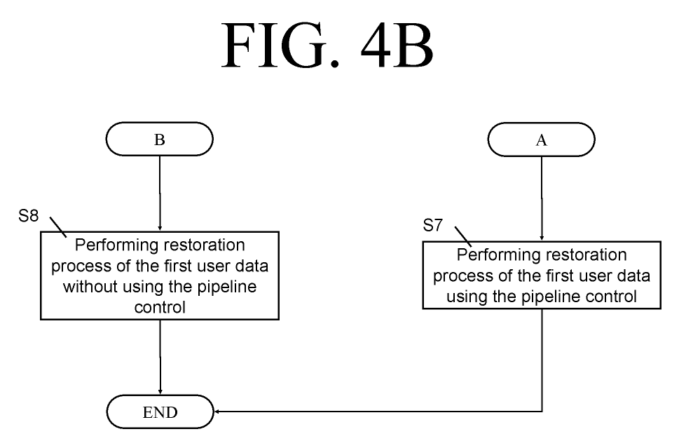

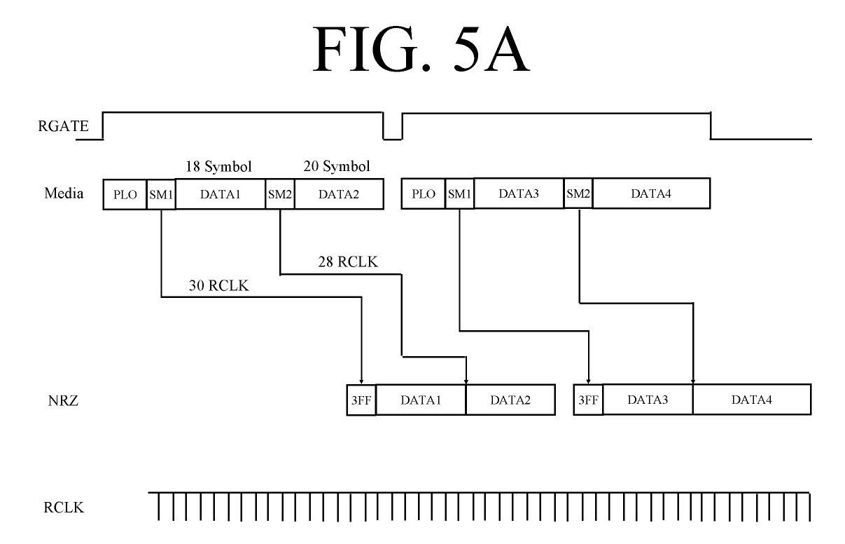

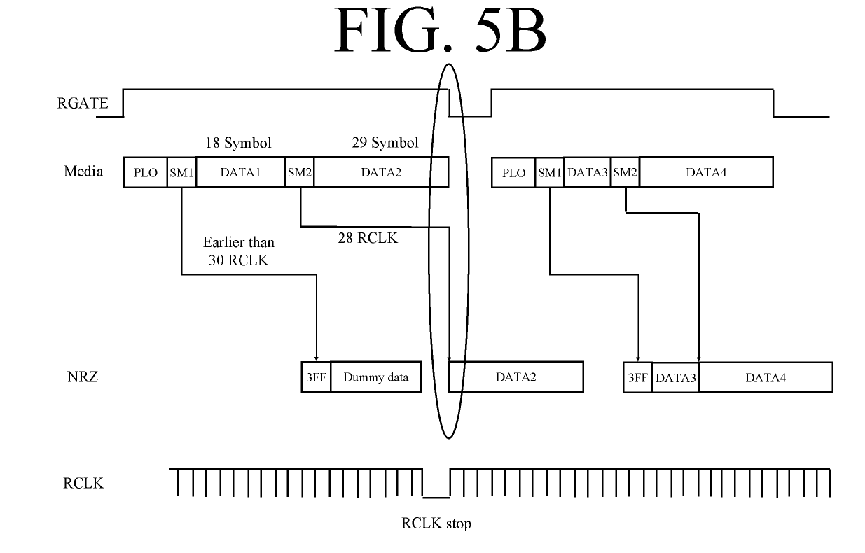

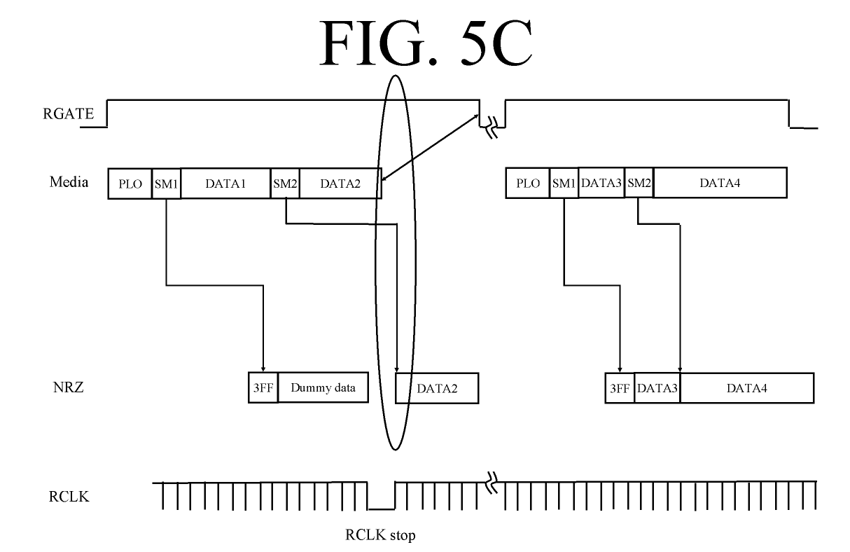

FIGS. 4A and 4B are flowcharts illustrating the read process. FIG. 5 is a timing diagram illustrating process timings of the read channel 220.

When the host apparatus 300 issues an instruction to read data recorded on the magnetic disk 110, the spindle motor 120 and the voice coil motor 130 operate in response to an instruction from the hard disk controller 240 illustrated in FIG. 2. The spindle motor 120 thus spins the magnetic disk 110 and the voice coil motor 130 positions the magnetic head 140 above the magnetic disk 110. When a head of a sector to be read is detected, the hard disk controller 240 asserts the read gate.

The magnetic disk 110 reads information recorded on the magnetic disk 110, sending a head output signal to the preamplifier 150 (step S1 in FIG. 4A). The preamplifier 150 amplifies the head output signal, and the amplified preamplifier signal is then transferred to the read channel 220. The preamplifier signal is successively supplied to the read channel 220 while the read gate is asserted.

FIG. 5A is a timing diagram of the standard read process.

The sync mark detector 221 in the read channel 220 detects a first sync mark in the preamplifier signal. If a first sync mark is detected (yes in step S2 in FIG. 4A), a standard read process is performed (step S3 in FIG. 4A).

During the standard read process, the read gate generating circuit 241 in the hard disk controller 240 is negated at the timing just after completion of read data. More specifically, the read gate generating circuit 241 is negated at the timing when successive data have been read out by the magnetic head 140. Since the read channel 220 performs the pipeline control in the standard read process, the process speed is increased.

If the detection of the first sync mark is successful, the detected first sync mark, the first user data and the second user data are successively outputted to the data demodulating circuit 222. The data demodulating circuit 222 demodulates the first sync mark and the first user data successive to the first sync mark into the NRZ data, and outputs the NRZ data to the hard disk controller via NRZ bus after delay of about 30 clocks. The data demodulating circuit 222 further demodulates the second user data into the NRZ data and outputs the NRZ data to the hard disk controller via NRZ bus after a delay of about 28 clocks. Thus, the demodulated NRZ data is successively transferred to the hard disk controller 240 via NRZ bus. The NRZ data is then transmitted to the host apparatus 300. When a head of next data segment to be read out is detected, the hard disk controller 240 asserts the read gate while the demodulation of the preceding data segment is carried out, the head starts to read out the next data segment in pipeline operation. The demodulation of the next data segment is carried out similarly, and first sync mark and first and second user data in NRZ format are transferred to the hard disk controller 240 successively.

If the detection of the first sync mark fails (no in step S2 in FIG. 4A), a restoration process of the first user data is performed using the ECC data (step S4 in FIG. 4A).

If the sector causing the detection of the first sync mark to fail is not a sector split by zone (no in step S5 in FIG. 4A), or if the sector causing the detection of the first sync mark to fail is a sector split by zone (yes in step S5 in FIG. 4A) with the data length being larger than a predetermined value (46 symbols here) (no in step S6 in FIG. 4A), a restoration process of the first user data using the pipeline control is performed (step S7 in FIG. 4B).

FIG. 5B is a timing diagram of the restoration process of the first user data performed using the pipeline control.

Even if the detection of the first sync mark fails, no split sector may take place or the data length may be larger than the predetermined value. In such a case, the read gate generating circuit 241 is negated at the timing corresponding to the data length of the read data in the same manner as in the standard read process.

If the detection of the first sync mark fails, the dummy data replacing the first user data is output to the data demodulating circuit 222 at a timing earlier than the timing in the standard read process (after a delay of about 30 symbols). A read clock is negated and the sync mark detector 221 waits for the detection of the second sync mark. When the second sync mark is detected, the second sync mark and the second user data are successively output to the data demodulating circuit 222 after a delay of about 28 clocks. Referring to FIG. 5B, the read gate generating circuit 241 is asserted at the moment the second sync mark is transferred to the data demodulating circuit 222. The data demodulating circuit 222 can detect the second sync mark. The data demodulating circuit 222 demodulates the second user data successive to the second sync mark into the NRZ data, and then demodulates the first user data using the ECC data.

If no split sector takes place or the data length is larger than the predetermined value, even with the detection failure of the first sync mark, the error recovery process is performed using the pipeline control. Both the high process speed and the reliability in the data reading are thus achieved. When a head of next data segment to be read out is detected, the hard disk controller 240 asserts the read gate while the demodulation of the preceding data segment is carried out, the head starts to read out the next data segment in pipeline operation. The demodulation of the next data segment is carried out similarly, and first sync mark and first and second user data in NRZ format are transferred to the hard disk controller 240 successively.

If the data length is equal to or smaller than the predetermined value (yes in step S6 in FIG. 4A) with the sector causing the detection of the first sync mark to fail being a split sector (yes in step S5 in FIG. 4A), the restoration process of the first user data is performed without using the pipeline process (step S8 in FIG. 4B).

FIG. 5C is a timing diagram illustrating the restoration process of the first user data without using the pipeline process. Restoring of data in pipeline operation from another of data segments subsequent to the certain data segment is suspended. The second user data information is converted into reproduced data while the restoring of data in pipeline operation is suspended.

If the detection of the first sync mark fails with the data length of the split sector being equal to or smaller than the predetermined value, the read gate generating circuit 241 is negated at the timing corresponding to the demodulation to the NRZ data.

If the detection of the second sync mark fails, the dummy data replacing the first user data is output to the data demodulating circuit 222 at an earlier timing than the timing in the standard read process (after a delay of about 30 symbols). If the second sync mark is detected, the second sync mark and the second user data are successively output to the data demodulating circuit 222 after a delay of about 28 clocks. The data demodulating circuit 222 demodulates the second user data successive to the first sync mark into the NRZ data, and then demodulates the first user data using the ECC data. Referring to FIG. 5C, the data demodulating circuit 222 reliably detects the second sync mark because the read gate is asserted at the completion of the demodulation of the second user data. The data demodulating circuit 222 can restore the first user data. Referring to FIG. 5C, the pipeline process is not applied. Since the process of FIG. 5C is specialized in the error recovery process, no consideration to subsequently reading the subsequent sectors is necessary. After the magnetic disk 110 rotating one revolution, the hard disk controller 240 asserts the read gate when a head of next data segment to be read out is detected. The read gate generation circuit 241 is negated at the timing just after completion of read data.

In accordance with this embodiment, the pipeline control is performed in the read channel if the first sync mark is detected, if no split sector takes place, or if the data length is larger than the predetermined value. The process speed is thus increased. If the first sync mark is not detected with the data length of the split sector being equal to or smaller than the predetermined value, the pipeline control is suspended and the error recovery process is reliably performed. The data is reliably read. In accordance with the present embodiment, the data length of the second user data can be set to be smaller than the predetermined value. The storage area is thus efficiently used if a split sector takes place. The track efficiency is improved.

In accordance with the data demodulating method, if the first sync mark is detected, the first user data and the second user data are demodulated and the read gate is negated in response to the detection of the first sync mark. If the first sync mark is not detected, the read gate is negated in response to the demodulating of the second user data performed in succession to the detection of the second sync mark. If the first sync mark is detected, the inputting of the sector data and the demodulating of the first and second user data are performed in parallel in a pipeline process. If the first sync mark is not detected, the second sync mark is reliably detected regardless of the data length of the first user data and the second user data. The error recovery is reliably performed without degrading track efficiency. In accordance with the data demodulating method, if the first sync mark is not detected, the pipeline process is suspended, thereby extending the read gating. If the first sync mark is not detected, a reliable execution of an error recovery process is more important than continuous inputting of subsequent sector data. The pipeline process is suspended only during the error recovery process. Both high process speed and reliability are thus achieved.

With this arrangement, the data demodulating circuit reliably performs an error recovery process regardless of a data length of each of the first user data and the second user data. A sector is efficiently split, leading to an increase in track efficiency.

The information storage device improves the track efficiency of the storage medium and reliably performs the error recovery process.

The data demodulating method, the data demodulating circuit and the information storage device in accordance with embodiments of the present art reliably perform the error recovery process and improves the track efficiency.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method of restoring data from a stream of data segments each including first synchronization information followed by first user data information, second synchronization information, and second user data information, the method comprising the steps of:
restoring data from one of the data segments by a process including:
detecting first synchronization information in said one of the data segments;
extracting first and second user data information on the basis of the first synchronization information; and
converting the first and second user data information into reproduced data after a delay time from the detecting of the first synchronization information;
repeating the restoring of data from another of the data segments such that data is successively restored in pipeline operation; and
carrying out error recovery operation in the event that the detecting of first synchronization information in a certain data segment is not successful by a process comprising:
detecting second synchronization information in said certain data segment;
extracting second user data information on the basis of the second synchronization information;
suspending the restoring of data in pipeline operation from another of the data segments subsequent to the certain data segment; and
converting the second user data information into reproduced data while the restoring of data in pipeline operation is suspended.

2. The method of claim 1, wherein the data segments includes an error correcting code.

3. The method of claim 2, further comprising generating the first user data information on the basis of the error correcting code when the detecting of first synchronization information in the certain data segment is not successful.

4. The method of claim 1, wherein the converting converts the first and second user data information into NRZ.

5. A memory device for restoring data from a stream of data segments each including first synchronization information followed by first user data information, second synchronization information, and second user data information, the memory device comprising:
a medium for storing the data segments; and
a controller for restoring data from one of the data segments by a process including:
detecting first synchronization information in said one of the data segments;
extracting first and second user data information on the basis of the first synchronization information; and
converting the first and second user data information into reproduced data after a delay time from the detecting of the first synchronization information;
repeating the restoring of data from another of the data segments such that data is successively restored in pipeline operation; and
carrying out error recovery operation in the event that the detecting of first synchronization information in a certain data segment is not successful by a process comprising:
detecting second synchronization information in said certain data segment;
extracting second user data information on the basis of the second synchronization information;
suspending the restoring of data in pipeline operation from another of the data segments subsequent to the certain data segment; and
converting the second user data information into reproduced data while the restoring of data in pipeline operation is suspended.

6. The memory device of claim 5, wherein the data segments includes an error correcting code.

7. The memory device of 6, wherein the controller generates the first user data information on the basis of the error correcting code when the detecting of first synchronization information in the certain data segment is not successful.

8. The memory device of claim 5, wherein the controller converts the first and second user data information into NRZ.
